(19) United States
(12) Patent Application Publication
(10) Pub. No.: US 2026/0075958 A1
(43) Pub. Date: Mar. 12, 2026

(54) HIGH VOLTAGE SEMICONDUCTOR DEVICE COMPRISING LEVEL SHIFTER WITH ELECTROSTATIC DISCHARGE SELF-PROTECTION STRUCTURE

(71) Applicant: SK keyfoundry Inc., Cheongju-si (KR)

(72) Inventors: Youngbae KIM, Sejong-si (KR); Eunkyung PARK, Cheongju-si (KR); Heehwan JI, Daejeon-si (KR)

(73) Assignee: SK keyfoundry Inc., Cheongju-si (KR)

(21) Appl. No.: 19/035,462

(22) Filed: Jan. 23, 2025

(30) Foreign Application Priority Data
Sep. 6, 2024 (KR) 10-2024-0121569

(51) Int. Cl. H10D 89/60; H03K 19/0185; H10D 30/01; H10D 30/65; H10D 62/10; H10D 64/00

(52) U.S. Cl. CPC H10D 89/713; H03K 19/018521; H10D 30/0281; H10D 30/65; H10D 62/106; H10D 64/112

(57) ABSTRACT

A semiconductor device includes a high side region and a low side region formed on a semiconductor substrate; a level shifter formed between the high side region and the low side region and including a source region, a gate region and a drain region; a guard ring formed adjacent to the level shifter; a first silicon controlled rectifier (SCR) disposed in the guard ring and including a first P-type highly doped (P+) region and a first N-type highly doped (N+) region formed on the semiconductor substrate; a second SCR disposed in the source region and including a second P+ region and a second N+ region; a third SCR disposed in the gate region and including a third P+ region and a third N+ region; and a fourth SCR disposed in the drain region and including a fourth P+ region and a fourth N+ region.

### CROSS REFERENCE TO RELATED APPLICATION

This application claims the benefit under 35 U.S.C. § 119(a) of Korean Patent Application No. 10-2024-0121569, filed on Sep. 6, 2024, in the Korean Intellectual Property Office, the entire disclosure of which is incorporated herein by reference for all purposes.

### BACKGROUND

### 1. Field

The following description relates to a high voltage integrated circuit (HVIC) comprising a level shifter, and more particularly, to a high voltage (HV) semiconductor device comprising a level shifter with electrostatic discharge (ESD) self-protection structure based on a silicon controlled rectifier (SCR).

### 2. Description of the Background The statements in this section merely provide background information related to the present disclosure and do not necessarily constitute prior art.

High voltage (HV) semiconductor devices above 600V, comprising a high-side gate driver IC and a low-side gate driver IC, have been widely used in motor drivers. HV semiconductor devices use bootstrap diodes and level shifters to operate at high voltages on the order of 600V or 1200V to drive power MOSFETs or discrete devices. While the HV semiconductor device is operating, high ESD currents can flow through several components of the HV semiconductor device, such as the bootstrap diode, level shifter, high-side gate driver IC, and the low-side gate driver IC. Several ESD structures have been proposed to block the high ESD currents flowing in these components. However, these ESD structures may require a large chip area. To reduce the large chip area, HV semiconductor devices with ESD self-protection structures may be required.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a semiconductor device comprises a high side region and a low side region formed on a semiconductor substrate; a level shifter formed between the high side region and the low side region and comprising a source region, a gate region and a drain region; a guard ring formed adjacent to the level shifter; a first silicon controlled rectifier (SCR) disposed in the guard ring and comprising a first P-type highly doped (P+) region and a first N-type highly doped (N+) region formed on the semiconductor substrate; a second SCR disposed in the source region and comprising a second P+ region and a second N+ region; a third SCR disposed in the gate region and comprising a third P+ region and a third N+ region; and a fourth SCR disposed in the drain region and comprising a fourth P+ region and a fourth N+ region.

The semiconductor device may further comprise a first P-type buried layer (PBL) and a first N-type buried layer (NBL) formed in the guard ring; and a first P-type deep well region (DPW) and a first N-type well region (NW) formed on the first PBL and the first NBL, respectively. The first P+ and N+ regions are formed on the first DPW and the first NW, respectively, and are electrically connected to a first ground electrode.

The level shifter may further comprise an N-type semiconductor region formed on the semiconductor substrate and a first field oxide layer (FOX) formed on the N-type semiconductor region.

The source region may further comprise a second PBL formed on the semiconductor substrate; a second DPW formed on the second PBL; and a first P-type body region (PBODY) formed on the second DPW. The second P+ and N+ regions may be formed in the first PBODY. The second P+ and N+ regions may be electrically connected to a body electrode and a source electrode, respectively.

The body electrode may be electrically connected to the first ground electrode or the source electrode.

The gate region may further comprise a first P-type top layer (PTOP) formed in the N-type semiconductor region; a second PBODY connected to the first PTOP; a first gate insulating film and a first gate electrode formed between the first PBODY and the second PBODY; and a gate field plate formed on the first FOX. The third SCR may be formed in the second PBODY.

The third SCR and the gate field plate may be electrically connected to a second ground electrode.

The drain region may comprise a second NBL formed on the semiconductor substrate; a second NW formed on the second NBL; and a drain field plate formed on the first FOX. The fourth SCR may be formed in the second NW, and the fourth SCR and the drain field plate may be electrically connected to a drain electrode.

The high side region may comprise a third NBL formed on the semiconductor substrate; a third NW and a third PBODY formed on the third NBL and spaced apart from each other; a fifth N+ region and a fifth P+ region formed in the third NW and the third PBODY, respectively; a second gate insulating film and a second gate electrode formed to overlap the third PBODY; and a six N+ region and a sixth P+ region formed between the third NW and the third PBODY.

In another general aspect, a semiconductor device may comprise a high side region and a low side region formed on a semiconductor substrate; a lateral double diffused MOS (LDMOS) device formed between the high side region and the low side region; a guard ring formed adjacent to the LDMOS device; and a high side device formed in the high side region; a first P-type highly doped (P+) region and a first N-type highly doped (N+) region formed in the guard ring; a source region, a gate region and a drain region formed in the LDMOS device; a second P+ region and a second N+ region formed in the source region; a third P+ region and a third N+ region formed in the gate region; and a fourth P+ region and a fourth N+ region formed in the drain region.

The guard ring may further comprise a first P-type buried layer (PBL) and a first N-type buried layer (NBL) formed parallel to each other on the semiconductor substrate; and a first P-type deep well region (DPW) and a first N-type well region (NW) formed on the first PBL and the first NBL, respectively. The first P+ and the first N+ regions may be formed on the first DPW and the first NW, respectively, and may be electrically connected to a first ground electrode.

The LDMOS device may further comprise an N-type semiconductor region formed on the semiconductor substrate; and a first field oxide layer (FOX) formed on the N-type semiconductor region. The source region may further comprise a second PBL formed on the semiconductor substrate; a second DPW formed on the second PBL; and a first P-type body region (PBODY) formed on the second DPW. The second P+ and N+ regions may be formed in the first PBODY and may be electrically connected to a body electrode and a source electrode, respectively.

The body electrode may be electrically connected to the first ground electrode or the source electrode.

The gate region may comprise a first P-type top layer (PTOP) formed in the N-type semiconductor region; a second PBODY connected to the first PTOP; a first gate insulating film and a first gate electrode formed on the first PBODY; and a gate field plate formed on the first FOX.

The second P+ region, the second N+ region and the gate field plate may be electrically connected to a second ground electrode.

The drain region may comprise a second NBL formed on the semiconductor substate; a second NW formed on the second NBL; and a drain field plate formed on the first FOX. The fourth P+ region and the fourth N+ region may be formed in the second NW, and the fourth P+ and N+ regions and the drain field plate may be electrically connected to a drain electrode.

The high side device may comprise a third NBL formed on the semiconductor substrate; a third NW and a third PBODY formed on the third NBL and spaced apart from each other; a fifth N+ region and a fifth P+ region formed in the third NW and the third PBODY, respectively; a second gate insulating film and a second gate electrode formed to overlap the third PBODY; and a sixth N+ region and a sixth P+ region formed between the third NW and the third PBODY.

According to various embodiments of the present disclosure, damage to internal components due to ESD can be prevented by using SCRs that can quickly dissipate this voltage when ESD is applied through terminals for connection to the outside.

Other features and aspects will be apparent from the following detailed description, the drawings, and the claims.

### BRIEF DESCRIPTION OF THE DRAWINGS

FIG. 1 illustrate a circuit diagram of a high voltage integrated circuit (HVIC) comprising a level shifter according to one embodiment;

FIG. 2 illustrate a top view of an HV semiconductor device having an ESD self-protection structure according to one embodiment of the present disclosure;

FIGS. 3 and 4 illustrate cross-sectional views of an HV semiconductor device with ESD self-protection structure according to one embodiment of the present disclosure;

FIG. 5 illustrates a cross-sectional view showing an ESD current path according to one embodiment of the present disclosure;

FIGS. 6 and 7 illustrate cross-sectional views of an HV semiconductor device with ESD self-protection structure according to another embodiment of the present disclosure;

FIG. 8 illustrates a cross-sectional view showing an ESD current path according to another embodiment of the present disclosure;

FIG. 9 illustrates a device simulation result for a reference structure to which SCR according to one embodiment is not applied;

FIG. 10 illustrates a device simulation result for a reference structure to which SCR according to one embodiment is applied;

FIG. 11 illustrates a lattice temperature result according to one embodiment;

FIG. 12 illustrates an electrical potential result according to one embodiment;

FIG. 13 illustrates an electrical potential result obtained by TCAD according to one embodiment; and

FIG. 14 illustrates a transmission line pulse (TLP) curve and DCBV result according to one embodiment.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

Description will now be given in detail according to exemplary embodiments disclosed herein, with reference to the accompanying drawings. For the sake of brief description with reference to the drawings, the same or equivalent components may be provided with the same reference numbers, and description thereof will not be repeated.

Hereinafter, a display device according to embodiments of the present disclosure will be described, referring to the accompanying drawings. It will be understood that when an element is referred to as being “connected with”, “on” or “coupled to” another element, the element can be directly connected with the other element or intervening elements may also be present. In contrast, when an element is referred to as being “directly connected with” another element, there are no intervening elements present.

Throughout the disclosure, each component can be provided as a single one or a plurality of ones, unless explicitly stated to the contrary. Terms such as “comprise” or “has” are used herein and should be understood that they are intended to indicate an existence of several components, functions or steps, disclosed in the specification, and it is also understood that greater or fewer components, functions, or steps may likewise be utilized.

It will be understood that the terms “first” and “second” are used herein to describe various components but these components should not be limited by these terms. The above terms are used only to distinguish one component from another. For example, a first component may be referred to as a second component and vice versa without departing from the scope of the embodiment.

Accordingly, it will be understood that although the terms first, second, etc. may be used herein to describe various elements, these elements should not be limited by these terms. These terms are generally only used to distinguish one element from another. The singular expressions comprise plural expressions unless the context clearly dictates otherwise.

The terms ‘part’ or ‘module’ used in embodiments may mean a software or hardware element such as an FPGA or ASIC, and the ‘part’ or ‘module’ may perform predetermined roles. However, ‘part’ or ‘module’ is not limited to the software or hardware. The “part” or “module” may be provided in an addressable storage medium and configured to cause one or more processors to execute. Accordingly, as one example, a “part” or “module” may comprise elements such as software elements, object-oriented software elements, class elements and task elements, as well as processes, functions, attributes, procedures, subroutines, segments of program code, drivers, firmware, microcode, circuitry, data, database, data structures, tables, arrays and variables. The functions provided within the elements and “parts” or “modules” may be combined and “sub-part” or “modules” or further separated into additional elements and “parts” or “modules.”

The steps of a method or algorithm described in connection with some embodiments of the present disclosure may be directly implemented in hardware, in a software module executed by a processor, or in a combination of the two. The software module may be provided in RAM memory, flash memory, ROM memory, EPROM memory, EEPROM memory, registers, a hard disk, a removable disk, a CD-ROM, or any other form of storage medium known in the art. An exemplary storage medium may be coupled to a processor such that the processor may read information from the storage medium and write information to the storage medium. Alternatively, a recording medium may be integral with the processor. The processor and the recording medium may be provided in an application specific integrated circuit ASIC. The ASIC may be provided in a user terminal.

Hereinafter, referring to the accompanying drawings, embodiments of the present disclosure will be described in detail, to be understood by those skilled in the art to which the present disclosure pertains. However, the present disclosure may be embodied in various modified examples, and is not limited to embodiments described herein.

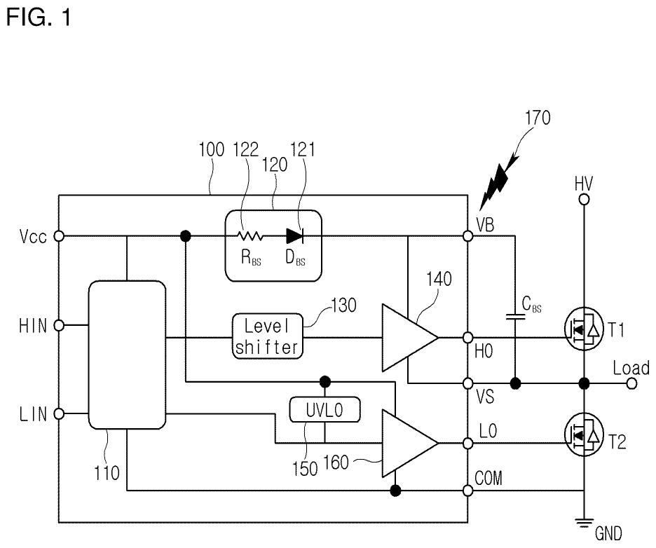

FIG. 1 illustrates a circuit diagram of a HVIC comprising a level shifter according to one embodiment.

The HVIC 100 comprising the level shifter shown in FIG. 1 may be a gate driver that provides a gate control signal of a switching element T1 and T2 based on external control.

Referring to FIG. 1, the HVIC 100 may comprise a control unit 110, a bootstrap circuit 120, a level shifter 130, a high side gate driver 140, an Under Voltage LockOut UVLO 150 and a low side gate driver 160 configured to provide a gate control signal to the gate of an external switching element T1 and T2.

The control unit 110 may provide control input to the high side gate driver 140 and the low side gate driver 160 for generating a gate control signal of the switching element T1 and T2 based on the external control signal.

The bootstrap 120 may comprise a bootstrap diode 121 and a bootstrap resistor 122. According to one embodiment, the bootstrap resistor 122 may not be provided. The bootstrap diode 121 may be a PN diode or a Schottky diode.

The bootstrap circuit 120 may power a gate control signal to drive the first switching element T1 along with an externally connected bootstrap capacitor C_{BS}.

The level shifter 130 may convert a low side signal into a high side signal. The level shifter 130 may comprise a lateral double diffused metal oxide semiconductor (LDMOS), an extended drain metal oxide semiconductor (EDMOS), or a diffused metal oxide semiconductor (DMOS). The element formed in the level shifter 130 must have a structure that can withstand high voltage (HV) because one side is connected to the HV region. The level shifter 130 may be referred to as an LDMOS device, a first semiconductor device, or a first HV device.

According to one embodiment, the high side gate driver 140 may generate a signal for controlling the first switching element T1, and the low side gate driver 160 may generate a signal for controlling the second switching element T2.

When the low side gate driver 160 is too small to operate, the UVLO 150 may have a function of detecting it and stopping operation. The UVLO 150 may perform low side detection and shutdown not only for the voltage related to the low side gate driver 160 shown in FIG. 1, but also for the input voltage or the voltage related to the high side gate driver 140.

The first switching element T1 and the second switching element T2 may be an N-type metal oxide semiconductor filed effect transistor (nMOSFET) or an insulated gate bipolar transistor (IGBT).

The first switching element T1 may be provided between a high voltage HV and a load, and a drain may be connected to the high voltage HV and a source may be connected to the load. A gate of the first switching element T1 may be connected to a high side output terminal HO of the HVIC 100, so that the first switching element T1 can be turned on or off by the voltage output from the high side output terminal HO. When the first switching element T1 is turned on, high voltage HV can be output to the load.

The second switching element T2 may be provided between a ground voltage GND and the load, so that the drain may be connected to the load and a source may be connected to the ground voltage GND. A gate of the second switching element T2 may be connected to a low side output terminal LO of the HVIC 100, so that the second switching element T2 can be turned on or off by the voltage output from the low side output terminal LO. The second switching element T2 may output ground voltage to the output load when it is turned on.

A source of the first switching element T1 and a drain of the second switching element T2 may be connected together to the load.

Referring to FIG. 1, to exchange signals with the outside and receive power required for operation, the HVIC 100 comprising the level shifter may comprise a voltage input terminal Vcc, a high side control input terminal HIN, a low side control input terminal LIN, a ground terminal COM, a HV terminal VB, a HV return voltage terminal VS, a high side output terminal HO and a low side output terminal LO.

The HVIC 100 comprising the level shifter may provide power required for driving through the voltage input terminal Vcc, and may be connected to an external ground voltage GND through the ground terminal COM to form a ground that is isolated from the outside.

The HVIC 100 comprising the level shifter may output a high side control signal via the high side output terminal HO, and the high side control signal may control the operation of the first switching element T1 in response to a logic signal input through the high side control input terminal HIN.

The high side output terminal HO may be connected to a gate of the first switching element T1 and configured to control the switching of the first switching element T1.

The HVIC 100 comprising the level shifter may output a low side control signal via the low side output terminal LO, and the low side control signal may control the operation of the second switching element T2 in response to a logical signal input through the low side control input terminal LIN. The low side output terminal LO may be connected to a gate of the second switching element T2 and configured to control the switching of the second switching element T2.

The first switching element T1 and the second switching element T2 may be controlled so that they do not turn on at the same time. For example, while the first switching element T1 is controlled to be turned on, the second switching element T2 may be controlled not to be turned on. Alternatively, while the first switching element T1 is controlled to be turned off, the second switching element T2 may be controlled to be turned on.

A bootstrap capacitor C_{BS} may be connected between the HV terminal VB and the HV return voltage terminal VS. In addition, the HV return voltage terminal VS may be connected to the load, a source of the first switching element T1, and a drain of the second switching element T2.

The bootstrap diode 121 disposed within the HVIC 100 comprising the level shifter and the external bootstrap capacitor C_{BS} may be connected in series with each other. An anode of the bootstrap diode 121 may be connected to a driving power supplied through the voltage input terminal Vcc via a bootstrap resistor 122. One end (e.g., cathode) of the bootstrap capacitor C_{BS} may be connected to a load, a HV return voltage terminal VS, a source of the first switching element T1, and a drain of the second switching element T2. A cathode of the bootstrap diode 121 and the other end of the bootstrap capacitor C_{BS} may be connected to each other, so that driving power can be supplied to the high side gate driver 140 at the connected point.

When the second switching element T2 is turned on and the first switching element T1 is turned off, the voltage applied to one end of the bootstrap capacitor C_{BS} becomes ground voltage GND so that a forward voltage can be applied to the bootstrap diode 121 and a forward bias current can flow. Due to the forward bias current, a voltage of a value obtained by subtracting the voltage applied to the bootstrap resistor 122 and the threshold voltage of the bootstrap diode 121 from the driving voltage input through the voltage input terminal Vcc may be applied to the HV terminal VB by the forward bias current. The bootstrap capacitor C_{BS} may be charged by the voltage output from the HV terminal VB.

When the first switching element T1 is turned on and the second switching element T2 is turned off, the voltage applied to one end of the bootstrap capacitor C_{BS} may become high voltage HV greater than the driving voltage Vcc, and a reverse bias voltage may be applied to the bootstrap diode 121, so the current flow may be blocked by the bootstrap diode. At this time, a value obtained by adding the voltage charged in the bootstrap capacitor C_{BS} to the high voltage HV applied to one end of the bootstrap capacitor C_{BS} may be applied to the HV terminal VB. As this voltage is output to the high side output terminal HO by driving the high side gate driver 140, the voltage between the source and gate of the first switching element T1 may become a charging voltage for the bootstrap capacitor C_{BS}. Since this charging voltage is greater than the threshold voltage of the first switching element T1, the first switching element T1 may be stably driven.

The HVIC 100 should be designed so as not to damage the internal circuit or semiconductor device, when an ESD surge 170 enters the HV terminal VB. The present disclosure proposes an ESD-resistant HV semiconductor device designed to allow high currents generated by the ESD surge 170 to flow through it by forming an SCR structure.

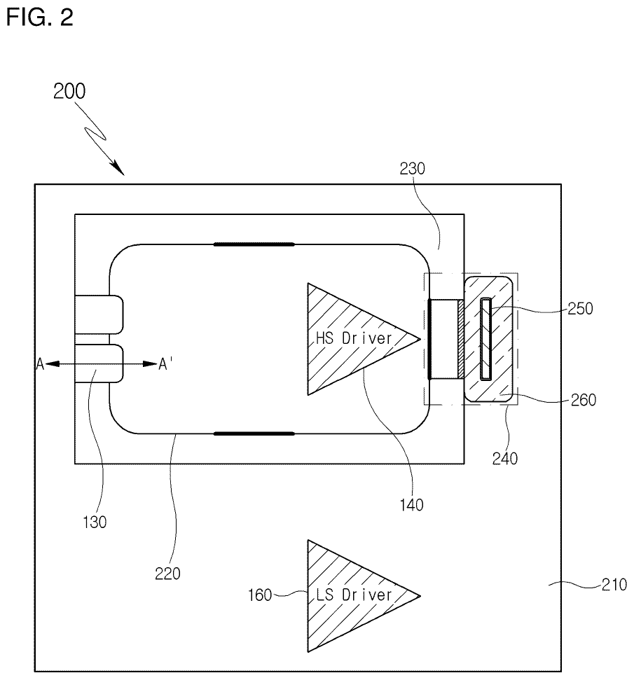

FIG. 2 illustrates a top view of a HV semiconductor device with ESD self-protection structure according to one embodiment of the present disclosure.

Referring to FIG. 2, the HV semiconductor device 200 may comprise a level shifter 130 for changing a signal level between a low side signal and a high side signal. The HV semiconductor device 200 may comprise a low side region 210 having elements that operate at a low voltage, and a high side region 220 having elements operating at a HV. For example, the elements operating in the low side region 210 may comprise a control unit 110, a UVLO 150 and a low side gate driver 160. The elements operating in the high side region may comprise a high side gate driver 140. Here, the low voltage range may be less than 30V, and the HV range may go up to 1200V. The high side semiconductor device may be formed in the high side region 220.

According to one embodiment, a junction isolation region 230 for electrically isolating the low side region 210 and the high side region 220 may be provided.

According to one embodiment, the junction isolation region 230 may comprise a HV blocking gate region (not shown). In the junction isolation region 230, a junction field effect transistor JFET or a lateral double diffused MOS (LDMOS) device may be disposed.

The HV diode region 240 may comprise a bootstrap diode 250 electrically connected to the source region from the HV diode and configured to pass a forward current into the drain region. Here, the bootstrap diode 250 may use a PN diode or a Schottky diode.

The forward current of the bootstrap diode 250 may charge the bootstrap capacitor C_{BS} to a sufficient voltage. Accordingly, applying sufficient voltage to the gate of the first switching element T1 may be made smooth. The embodiment shown in FIG. 2 shows that one bootstrap diode 250 is placed, but multiple bootstrap diodes may be placed unless one diode does not provide sufficient forward current.

The HV diode region 240 may further comprise a PNP guard ring 260 surrounding the bootstrap diode 250 to protect the bootstrap diode 250 from HV.

The PNP guard ring 260 may be implemented in a form of completely surrounding the bootstrap diode 250 to protect the bootstrap diode 250 from HV. This is because the bootstrap diode 250 has a structure that is vulnerable to HV in the high side region 220. The wider the PNP guard ring 260, the better it is for protecting the bootstrap diode 250 from HV.

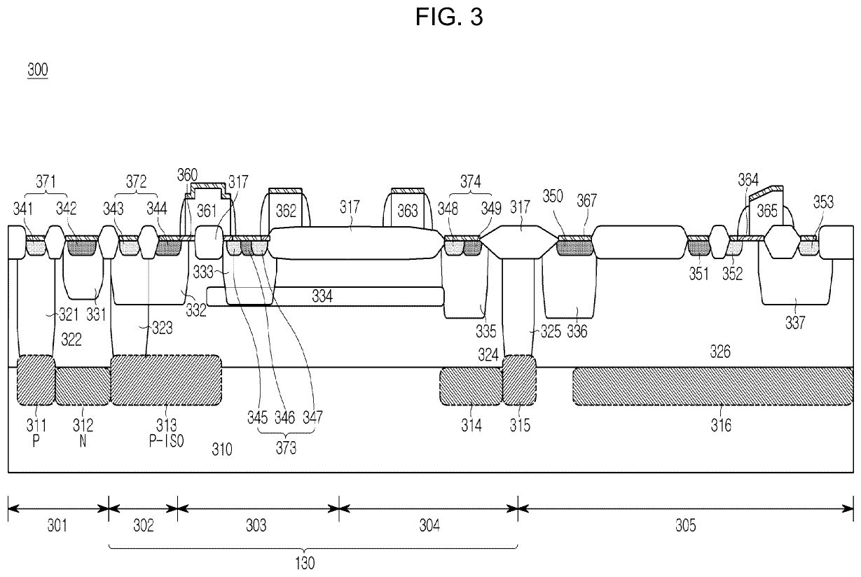

Referring to FIGS. 2 and 3, the HV diode region 240 may comprise a first SCR 371, a second SCR 372, and a third SCR 373. As will be described in detail in FIG. 3, the first SCR 371, the second SCR 372, and the third SCR 373 each comprise an N+ region and a P+ region. By adding the SCR (i.e., silicon controlled rectifier) or a thyristor to the HV diode region 240, the HVIC may be protected from electro static discharge (ESD). For example, the HVIC may be protected from ESD by adding an SCR to the HV diode region 240 that spans the low side region 210 and the high side region 220. The SCR is a device with a PNPN structure, which is used as if there were two transistors, namely PNP and NPN. When a certain amount of current is applied to the gate of the SCR, the anode and cathode of the SCR become conductive and the SCR is turned on, so it allows current to flow between the anode and cathode. When the current between the anode and cathode falls below a certain value, the SCR turns off and no current flows.

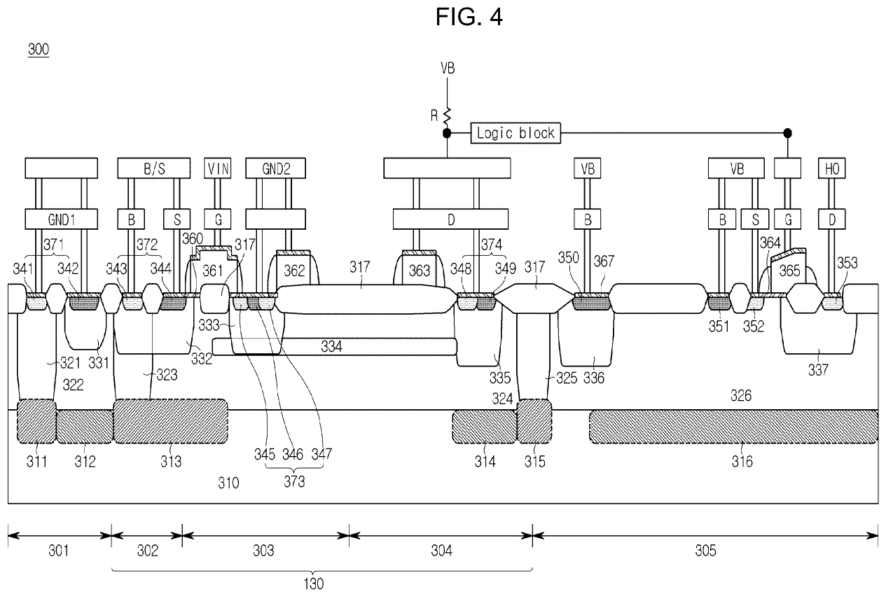

FIGS. 3 and 4 illustrate cross-sectional views of a HV semiconductor device with ESD self-protection structure according to one embodiment of the present disclosure. FIGS. 3 and 4 illustrate cross-sectional views showing the A-A′ cross-section of FIG. 2.

Referring to FIGS. 3 and 4, the HV semiconductor device 300 with ESD self-protection structure according to one embodiment may comprise a guard ring 301, a high side device 305, and a level shifter 130 formed between the high side region 220 and the low side region 210. The level shifter 130 may comprise a source region 302, a gate region 303 and a drain region 304. The level shifter 130 may be referred to as an LDMOS device.

The guard ring 301 may comprise a first silicon controlled rectifier (SCR) 371 formed on the semiconductor substrate 310 and comprising a first P-type highly doped (P+) region 341 and a first N-type highly doped (N+) region 342. The guard ring 301 may further comprise a first P-type buried layer (PBL) 311 and a first N-type buried layer (NBL) 312 formed parallel to each other on the semiconductor substrate 310; and a first deep P-type well region (DPW) 321 and a first N-type well region (NW) 331 formed on the first PBL 311 and the first NBL 312, respectively. The first P+ region 341 and the first N+ region 342 may be formed on the first DPW 321 and the first NW 331, respectively. The first SCR 371 comprising the first P+ region 341 and the first N+ region 342 may be connected to a first ground electrode (GND1) (See FIG. 4).

The level shifter 130 may comprise a lateral double diffused metal oxide semiconductor (LDMOS), an extended drain metal oxide semiconductor (EDMOS), or a diffused metal oxide semiconductor (DMOS). Herein, an N-type LDMOS (nLDMOS) may be implemented for the level shifter 130. The nLDMOS may further comprise an N-type semiconductor region 322, 324 and 326 formed on the semiconductor substrate 310, and a first field oxide layer (FOX) 317 formed on the N-type semiconductor region 322, 324 and 326. As stated above, the level shifter 130 may comprise a source region 302, a gate region 303 and a drain region 304. The source region 302 may comprise a second SCR 372 comprising a second P+ region 343 and a second N+ region 344. The gate region 303 may comprise a third SCR 373 comprising third P+ regions 345 and 347 and a third N+ region 346. The drain region 304 may comprise a fourth SCR 374 comprising a fourth P+ region 348 and a fourth N+ region 349.

The source region 302 may further comprise a second PBL 313 formed on the semiconductor substrate 310; a second DPW 323 formed on the second PBL 313; and a first P-type body region (PBODY) 332 formed on the second DPW 323. The second P+ region 343 and the second N+ region 344 may be formed in the first PBODY 332. The second P+ region 343 and the second N+ region 344 may be electrically connected to a body electrode B and a source electrode S, respectively. The body electrode B and the source electrode S may be electrically connected to a common body/source electrode B/S.

The gate region 303 may further comprise a first P-type top layer (PTOP) 334 formed in the N-type semiconductor region 322, 324 and 326; a second PBODY 333 formed in connection to the first PTOP 334; a first gate insulating film 360 formed between the first PBODY 332 and the second PBODY 333; a first gate electrode 361 formed on the first gate insulating film 360; and a gate field plate 362 formed on the first FOX 317. The first PBODY 332 may provide a channel region in the nLDMOS. The first gate electrode 361 may be electrically connected to a gate terminal G which may be electrically connected to an input voltage VIN. The third SCR 373 may be formed in the second PBODY 333. The third SCR 373 and the gate field plate 362 may be electrically connected to the ground electrode GND2.

The first gate electrode 361 may be formed on the FOX 317 and may extend to the second PBODY 333. Therefore, the first gate electrode 361 may overlap the N-type semiconductor region 324 and the second PBODY 333. A portion of the first gate electrode 361 overlapping with the FOX 317 may reduce the surface electric field (RESURF) of the HV semiconductor device 300. The first P-type top layer (PTOP) 334 may also reduce the surface electric field (RESURF) of the HV semiconductor device 300.

The drain region 304 may further comprise a second NBL 314 formed on the semiconductor substrate 310; a second NW 335 formed on the second NBL 314; and a drain field plate 363 formed on the first FOX 317. The fourth SCR 374 may be formed in the second NW 335. The fourth SCR 374 and the drain field plate 363 may be electrically connected to the drain electrode D. In addition, the drain electrode D may be electrically connected to a HV terminal VB via a resistor R. The drain electrode D may be electrically connected to a second gate electrode 365 of the high side device 305 through a logic block.

The high side device 305 may comprise an N-type or a P-type lateral double diffused metal oxide semiconductor (LDMOS) or an extended drain metal oxide semiconductor (EDMOS). In the present disclosure, a P-type LDMOS device is described as an example. The P-type LDMOS device 305 may comprise a third NBL 316 formed on the semiconductor substrate 310; a third NW 336 and a third PBODY 337 formed on the third NBL 316 and spaced apart from each other; a fifth N+ region 350 and a fifth P+ region 353 formed in the third NW 336 and the third PBODY 337, respectively; a second gate insulating film 364 and a second gate electrode 365 formed to overlap the third PBODY 337; and a sixth N+ region 351 and a sixth P+ region 352 formed between the third NW 336 and the third PBODY 337. The sixth P+ region 352, the fifth P+ region 353 and the sixth N+ region 351 may be considered as the source region, drain region and body contact region of the high side device 305, respectively. The third NW 336 and the third PBODY 337 of the high side device 305 may be electrically connected to the HV terminal VB and the high side output terminal HO.

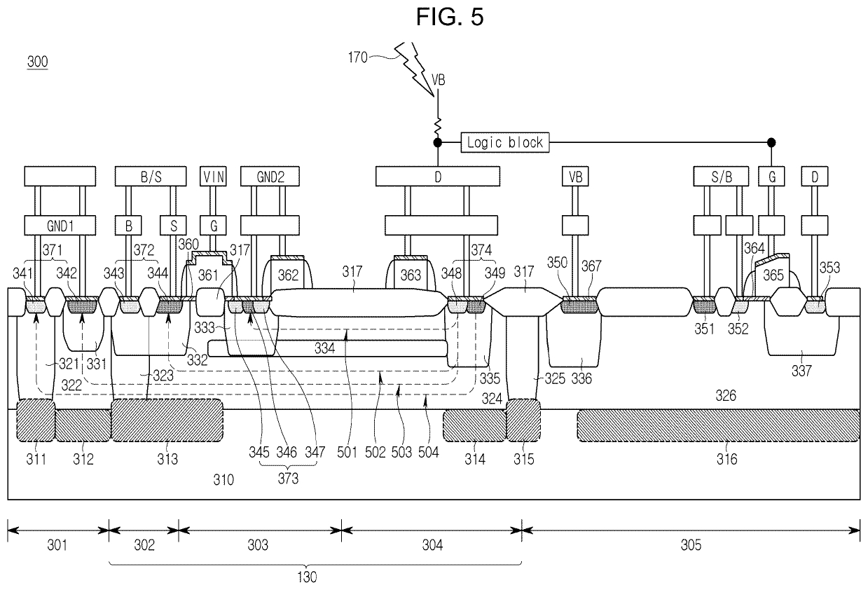

FIG. 5 illustrates a cross-sectional view showing an ESD current path according to one embodiment of the present disclosure.

FIG. 5 illustrates four ESD current paths when an ESD surge 170 is introduced into the HV terminal VB electrically connected to the fourth SCR 374. Herein, the ESD current path may mean low resistance discharge path.

A first ESD current path 501 may start from the fourth P+ region 348 of the fourth SCR 374 to the third P+ region 345 or 347 of the third SCR 373.

A second ESD current path 502 may start from the fourth N+ region 349 of the fourth SCR 374 to the third N+ region 346 of the third SCR 373.

A third ESD current path 503 may start from the fourth P+ region 348 of the fourth SCR 374 to the second P+ region 343 of the second SCR 372.

A fourth ESD current path 504 may start from the fourth N+ region 349 of the fourth SCR 374 to the second N+ region 344 of the second SCR 372.

Therefore, the HV semiconductor device 300 may discharge the ESD current through the first SCR 371 to the fourth SCR 374.

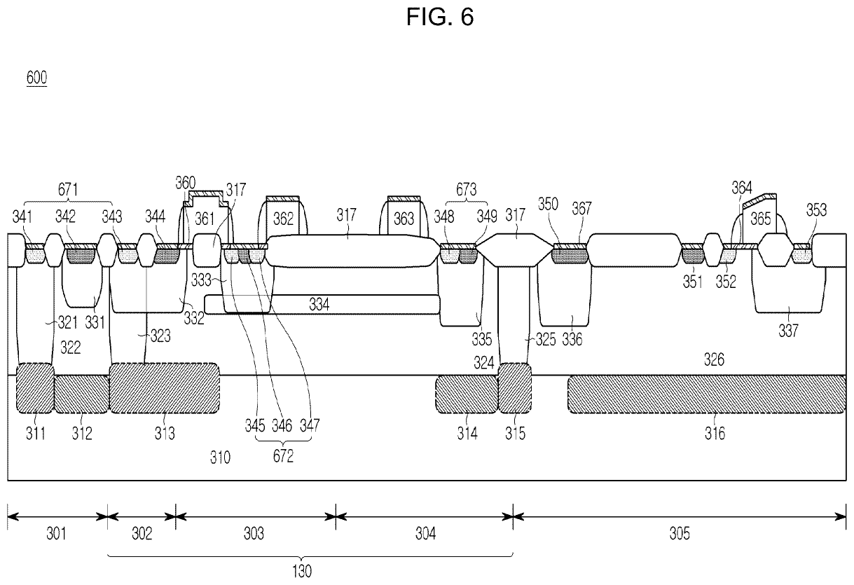

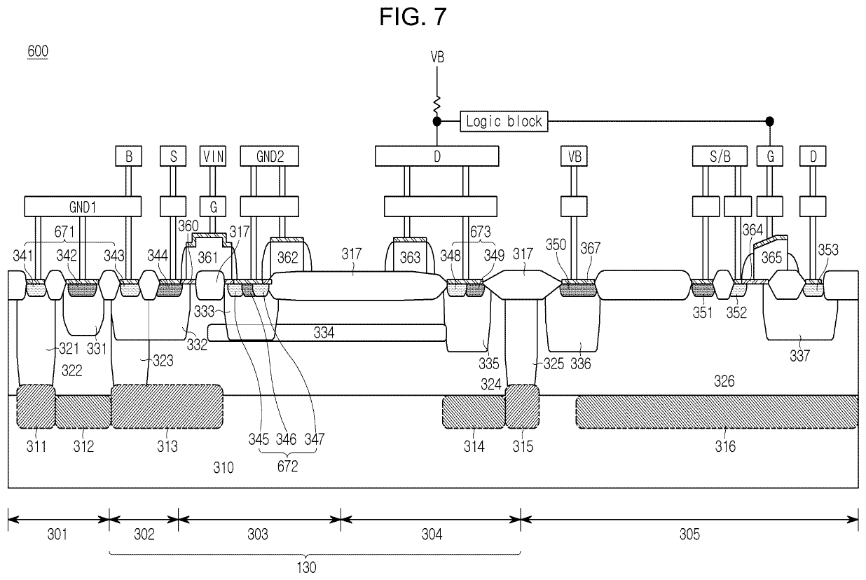

FIGS. 6 and 7 illustrate cross-sectional views of the HV semiconductor device with ESD self-protection structure according to another embodiment of the present disclosure. FIGS. 6 and 7 illustrate cross-sectional views showing the A-A′ cross-section of FIG. 2.

Referring to FIGS. 6 and 7, the HV semiconductor device 600 with improved ESD protection function according to another embodiment may comprise the guard ring 301, the high side device 305, and the level shifter 130 formed between the high side region 220 and the low side region 210.

FIGS. 6 and 7 differ from FIG. 3 with respect to the first SCR 671, and the others are similar to each other.

The first SCR 671 may comprise the first P+ region 341, the first N+ region 342 and the second P+ region 343. The first P+ region 341, the first N+ region 342 and the second P+ region 343 may be electrically connected to the first ground electrode GND1. The second N+ region 344 in the source region 302 may be solely connected to the source terminal S. Accordingly, there is an advantage that a ground voltage and other voltages may be applied to the source terminal S.

The second SCR 672 may comprise the third P+ region 345 and 347 and the third N+ region 346. The third P+ region 345 and 347 and the third N+ region 346 may be electrically connected to the second ground electrode GND2.

The third SCR 673 may comprise the fourth P+ region 348 and the fourth N+ region 349. The fourth P+ region 348 and the fourth N+ region 349 may be electrically connected to a drain electrode D.

The guard ring 301 may further comprise a first PBL 311 and a first NBL 312 formed on the semiconductor substrate 310; and a first DPW 321 and a first NW 331 formed on the first PBL 311 and the first NBL 312, respectively. The first P+ region 341 and the first N+ region 342 may be formed on the first DPW 321 and the first NW 331, respectively. The first P+ region 341 and the first N+ region 342 may be connected to a first ground electrode GND.

The level shifter 130 may comprise a lateral double diffused metal oxide semiconductor (LDMOS), an extended drain metal oxide semiconductor (EDMOS), or a diffused metal oxide semiconductor (DMOS). Herein, an N-type LDMOS (nLDMOS) may be implemented for the level shifter 130. The nLDMOS may further comprise an N-type semiconductor region 322, 324 and 326 formed on the semiconductor substrate 310, and a first field oxide layer (FOX) 317 formed on the N-type semiconductor region 322, 324 and 326. As stated above, the level shifter 130 may comprise a source region 302, a gate region 303 and a drain region 304.

The level shifter 130 comprising the source region 302, the gate region 303 and the drain region 304 may mean a level shifter device, and it may further comprise a N-type semiconductor region 322, 323 and 326; and a first FOX 317 formed on the N-type semiconductor region 322, 324 and 326.

The source region 302 may further comprise a second PBL 313 formed on the semiconductor substrate 310; a second DPW 323 formed on the second PBL 313; and a first PBODY 332 formed on the second DPW 323. The second P+ region 343 and the second N+ region 344 may be formed in the first PBODY 332. The second P+ region 343 and the second N+ region 344 may be electrically connected to a body electrode B and a source electrode S, respectively. Here, the body electrode B may be electrically connected to the first ground electrode GND.

The gate region 303 may further comprise a first PTOP 334 formed in the N-type semiconductor region 322, 324 and 326; a second PBODY 333 connected to the first PTOP 334; a first gate insulating film 360 and a first gate electrode 361 formed on the first PBODY 332; and a gate field plate 362 formed on the first FOX 317.

The drain region 304 may comprise a second NBL 314 formed on the semiconductor substrate 310; a second NW 335 formed on the second NBL 314; and a drain field plate 363 formed on the first FOX 317. The fourth P+ region 348 and the fourth N+ region 349 may be formed on the second NW 335. The fourth P+ region 348, the fourth N+ region 349 and the drain field plate 363 may be electrically connected to a drain electrode D.

The high side device 305 may comprise a third NBL 316 formed on the semiconductor substrate 310; a third NW 336 and a third PBODY 337 formed on the third NBL 316 and spaced apart from each other; a fifth N+ region 350 and a fifth P+ region 353 formed on the third NW 336 and the third PBODY 337, respectively; a second gate insulating film 364 and a second gate electrode 365 formed to overlap the third PBODY 337; and a sixth N+ region 351 and a sixth P+ region 352 formed between the third NW 336 and the third PBODY 337. The other description of this embodiment is similar to the embodiment of FIGS. 3 and 4, thereby omitting detailed description thereof.

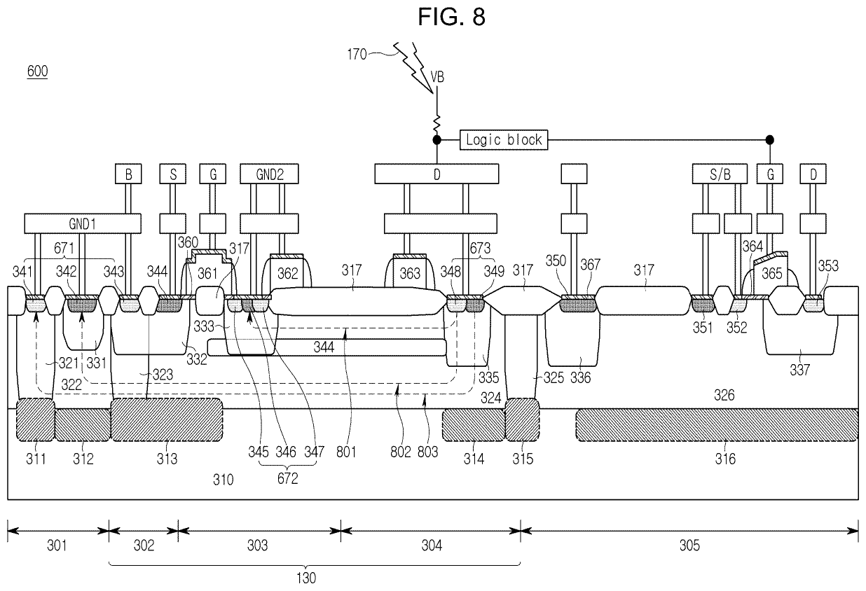

FIG. 8 illustrates a cross-sectional view showing an ESD current path according to another embodiment of the present disclosure.

FIG. 8 shows four ESD current paths when an ESD surge 170 is introduced into the HV terminal VB electrically connected to the third SCR 673. Herein, the ESD current path may be referred to as a low-resistance discharge path.

A first ESD current path 801 may start from the fourth P+ region 348 of the third SCR 673 to the third P+ region 345 or 347 of the second SCR 672.

A second ESD current path 802 may start from the fourth N+ region 349 of the third SCR 673 to the third N+ region 346 of the second SCR 672.

A third ESD current path 803 may start from the fourth P+ region 348 of the third SCR 673 to the second P+ region 343 of the first SCR 671.

A fourth ESD current path 804 may start from the fourth N+ region 349 of the third SCR 673 to the first N+ region 342 of the first SCR 671.

Therefore, the HV semiconductor device 300 may discharge the ESD current through the first SCR 671 to the third SCR 673.

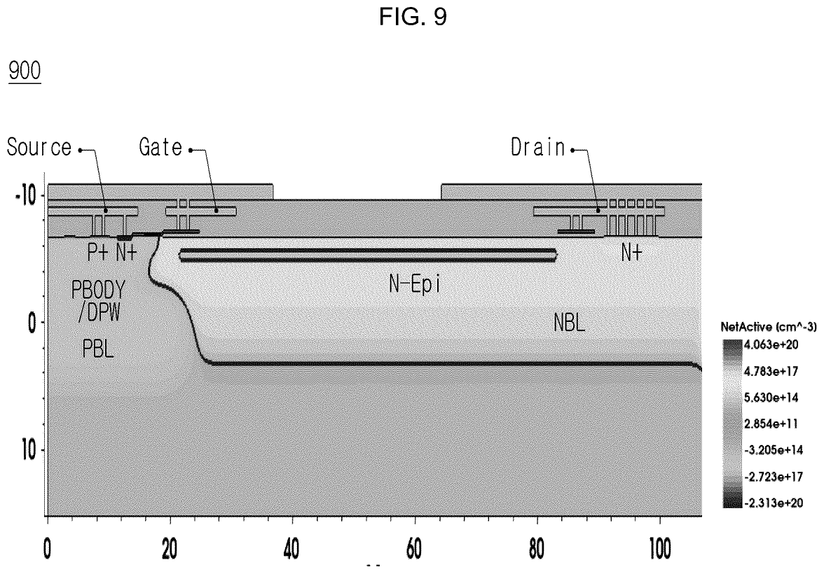

FIG. 9 illustrates a device simulation result for a reference structure to which SCR according to one embodiment is not applied.

FIG. 9 illustrates technology computer-aided design (TCAD) devise simulation for a reference structure 900 to which SCR is not applied for comparison with the embodiment of the present disclosure, and the doping profile for each region of the reference structure 900 may be shown. The portion marked as “Source” in the reference structure 900 is electrically connected to the second P+ region 343 and the second N+ region 344 of the source region 302. The portion marked as “Gate” is electrically connected to a gate electrode 361 of the gate region 303. “Gate” is electrically connected to a gate terminal. The portion marked as “Drain” is electrically connected only to a fourth N+ region 349 of the drain region 304. The reference structure 900 has no fourth P+ region 348 in the drain region 304.

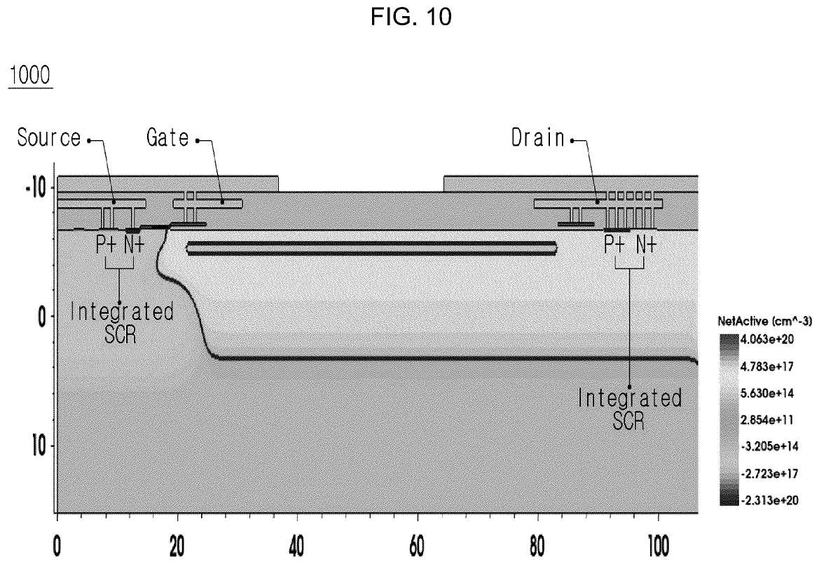

FIG. 10 illustrates a device simulation result for a reference structure to which SCR according to one embodiment is applied. FIG. 10 illustrates the result of TCAD device simulation for the cross-section view of FIG. 4.

Referring to FIG. 10, it shows the doping profile of each region in the structure 1000 to which one embodiment of the present disclosure is applied. It can be said that this structure is the same as the structure described in FIG. 4. It is similar to FIG. 9, except for the portion marked as “Drain”. The portion marked as “Drain” is related to the fourth SCR 374 of FIG. 4. The fourth P+ region 348 and the fourth N+ region 349 may be connected to a drain electrode D.

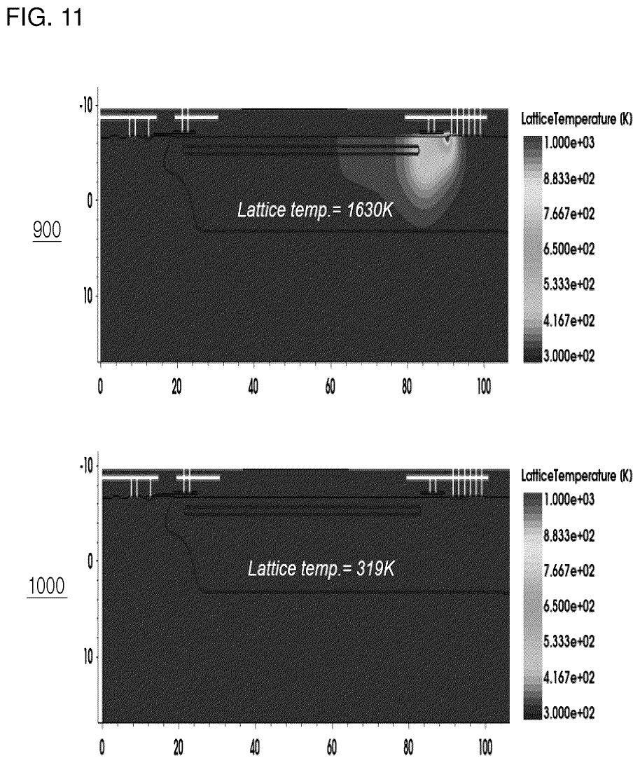

FIG. 11 illustrates the results of electrical potentials calculated by TCAD according to one embodiment of the present disclosure.

Referring to FIG. 11, it shows the lattice temperature results for the reference structure 900 used in FIG. 9 and the structure 1000 to which one embodiment of the present disclosure is applied. The lattice temperature results are the results of changing a voltage at Drain and applying a ground voltage to Gate and Source. It is shown that the structure 1000 to which the embodiment of the present disclosure is applied has a lower lattice temperature result than the reference structure 900. It is shown that the reference structure 900 has a very high lattice temperature of 1630K near the drain region. Regions with high lattice temperatures are susceptible to electrical stress, and device failure may easily occur. That is, a high lattice temperature means that a large amount of current flows momentarily in the drain region, after rapidly increasing the temperature of the semiconductor substrate. In this case, the silicon in the drain region may melt, which might cause a silicon pit and is very likely to cause device characteristic defects.

On the other hand, it is shown that the structure 1000 to which the embodiment is applied has a much lower lattice temperature 319K than the lattice temperature of 1630K of the reference structure. In the structure 1000 to which the embodiment of the present disclosure is applied, a stable lattice temperature value is shown.

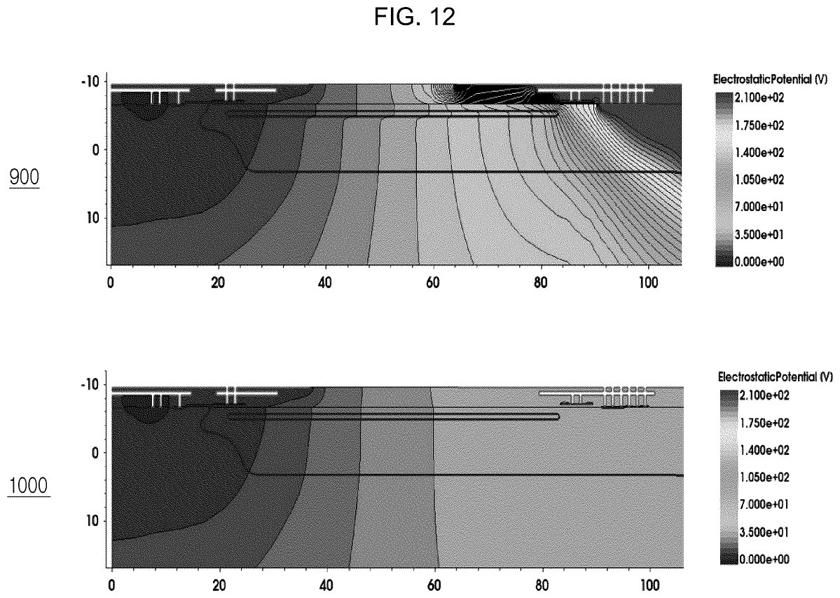

FIG. 12 illustrates an electrical potential result according to one embodiment.

Referring to FIG. 12, it shows the results of electrical potentials for the reference structure 900 used in FIG. 9 and the structure 1000 to which an embodiment of the present disclosure is applied. The electrical potential results may be the results of changing a voltage at the drain and applying a ground voltage to the gate and the source. It is shown that the structure 1000 to which the embodiment of the present disclosure is applied has more uniform potential results than the reference structure 900. In the reference structure 900, the electrical potential near the drain region is much higher than the electrical potential near the source region. The region with high electrical potential is susceptible to electrical stress, which easily causes device failure. On the other hand, it is shown that in the structure 1000 to which the embodiment of the present disclosure is applied, the region near the drain has an electrical potential that is not significantly different from that of other gate and source regions.

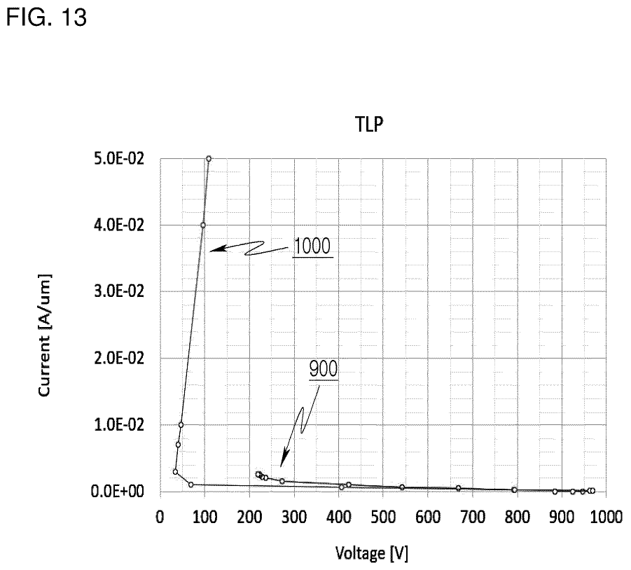

FIG. 13 illustrates the results of transmission line pulse curve (TLP) curve according to one embodiment.

Referring to FIG. 13, the results for TLP curve for the reference structure 900 and the results for TLP curve for the structure 1000 to which the embodiment of the present disclosure are compared. It is shown that the structure 1000 to which the embodiment of the present disclosure is applied can secure a good first triggering voltage Vt1 and a good holding voltage Vh through the TLP curve.

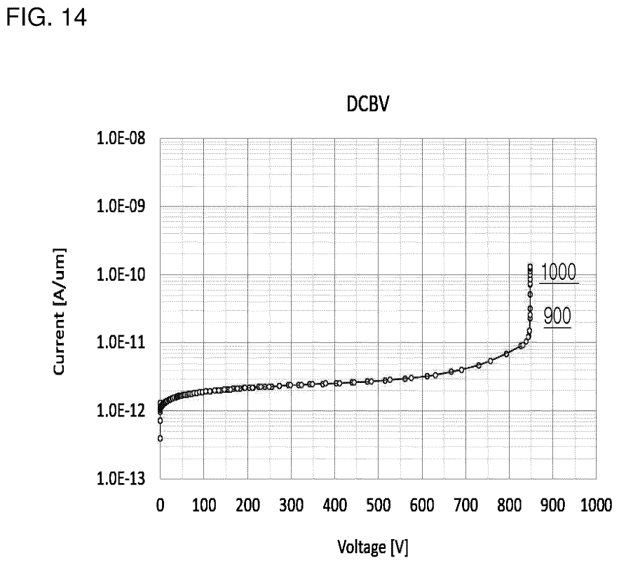

FIG. 14 illustrates the results of DCBV (DC breakdown voltage) according to one embodiment.

Referring to FIG. 14, the DCBV results for the reference structure 900 and the structure 1000 to which the embodiment of the present disclosure is applied are compared. The reference structure 900 and the structure 1000 to which the embodiment of the present disclosure is applied are shown to have similar DCBV values of approximately 850V.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor device comprising:
a high side region and a low side region formed on a semiconductor substrate;
a level shifter formed between the high side region and the low side region and comprising a source region, a gate region and a drain region;
a guard ring formed adjacent to the level shifter;
a first silicon controlled rectifier (SCR) disposed in the guard ring and comprising a first P-type highly doped (P+) region and a first N-type highly doped (N+) region formed on the semiconductor substrate;
a second SCR disposed in the source region and comprising a second P+ region and a second N+ region;
a third SCR disposed in the gate region and comprising a third P+ region and a third N+ region; and
a fourth SCR disposed in the drain region and comprising a fourth P+ region and a fourth N+ region.

2. The semiconductor device of claim 1, further comprising:
a first P-type buried layer (PBL) and a first N-type buried layer (NBL) formed in the guard ring; and
a first P-type deep well region (DPW) and a first N-type well region (NW) formed on the first PBL and the first NBL, respectively,
wherein the first P+ and N+ regions are formed on the first DPW and the first NW, respectively, and are electrically connected to a first ground electrode.

3. The semiconductor device of claim 2, wherein the level shifter further comprises:
an N-type semiconductor region formed on the semiconductor substrate; and
a first field oxide layer (FOX) formed on the N-type semiconductor region.

4. The semiconductor device of claim 3, wherein the source region further comprises:
a second PBL formed on the semiconductor substrate;
a second DPW formed on the second PBL; and
a first P-type body region (PBODY) formed on the second DPW,
wherein the second P+ and N+ regions are formed in the first PBODY, and
wherein the second P+ and N+ regions are electrically connected to a body electrode and a source electrode, respectively.

5. The semiconductor device of claim 4, wherein the body electrode is electrically connected to the first ground electrode or the source electrode.

6. The semiconductor device of claim 4, wherein the gate region further comprises:
a first P-type top layer (PTOP) formed in the N-type semiconductor region;
a second PBODY connected to the first PTOP;
a first gate insulating film and a first gate electrode formed between the first PBODY and the second PBODY; and
a gate field plate formed on the first FOX, and
wherein the third SCR is formed in the second PBODY.

7. The semiconductor device of claim 6, wherein the third SCR and the gate field plate are electrically connected to a second ground electrode.

8. The semiconductor device of claim 4, wherein the drain region comprises:
a second NBL formed on the semiconductor substrate;
a second NW formed on the second NBL; and
a drain field plate formed on the first FOX,
wherein the fourth SCR is formed in the second NW, and
wherein the fourth SCR and the drain field plate are electrically connected to a drain electrode.

9. The semiconductor device of claim 1, wherein the high side region comprises:
a third NBL formed on the semiconductor substrate;
a third NW and a third PBODY formed on the third NBL and spaced apart from each other;
a fifth N+ region and a fifth P+ region formed in the third NW and the third PBODY, respectively;
a second gate insulating film and a second gate electrode formed to overlap the third PBODY; and
a sixth N+ region and a sixth P+ region formed between the third NW and the third PBODY.

10. A semiconductor device comprising:
a high side region and a low side region formed on a semiconductor substrate;
a lateral double diffused MOS (LDMOS) device formed between the high side region and the low side region;
a guard ring formed adjacent to the LDMOS device;
a high side device formed in the high side region;
a first P-type highly doped (P+) region and a first N-type highly doped (N+) region formed in the guard ring;
a source region, a gate region and a drain region formed in the LDMOS device;
a second P+ region and a second N+ region formed in the source region;
a third P+ region and a third N+ region formed in the gate region; and
a fourth P+ region and a fourth N+ region formed in the drain region.

11. The semiconductor device of claim 10, wherein the guard ring further comprises:
a first P-type buried layer (PBL) and a first N-type buried layer (NBL) formed parallel to each other on the semiconductor substrate; and
a first P-type deep well region (DPW) and a first N-type well region (NW) formed on the first PBL and the first NBL, respectively, and
wherein the first P+ region and the first N+ region are formed on the first DPW and the first NW, respectively, and are electrically connected to a first ground electrode.

12. The semiconductor device of claim 11, wherein the LDMOS device further comprises:
an N-type semiconductor region formed on the semiconductor substrate; and
a first field oxide layer (FOX) formed on the N-type semiconductor region,
wherein the source region further comprises:
a second PBL formed on the semiconductor substrate;
a second DPW formed on the second PBL; and
a first P-type body region (PBODY) formed on the second DPW, and
wherein the second P+ and N+ regions are formed in the first PBODY and are electrically connected to a body electrode and a source electrode, respectively.

13. The semiconductor device of claim 12, wherein the body electrode is electrically connected to the first ground electrode or the source electrode.

14. The semiconductor device of claim 12, wherein the gate region comprises:
a first P-type top layer (PTOP) formed in the N-type semiconductor region;
a second PBODY connected to the first PTOP;
a first gate insulating film and a first gate electrode formed on the first PBODY; and
a gate field plate formed on the first FOX.

15. The semiconductor device of claim 14, wherein the second P+ region, the second N+ region and the gate field plate are electrically connected to a second ground electrode.

16. The semiconductor device of claim 12, wherein the drain region comprises:
a second NBL formed on the semiconductor substrate;
a second NW formed on the second NBL; and
a drain field plate formed on the first FOX, and
wherein the fourth P+ and N+ regions are formed in the second NW, and the fourth P+ and N+ regions and the drain field plate are electrically connected to a drain electrode.

17. The semiconductor device of claim 16, wherein the high side device comprises:
a third NBL formed on the semiconductor substrate;
a third NW and a third PBODY formed on the third NBL and spaced apart from each other;
a fifth N+ region and a fifth P+ region formed in the third NW and the third PBODY, respectively;
a second gate insulating film and a second gate electrode formed to overlap the third PBODY; and
a sixth N+ region and a sixth P+ region formed between the third NW and the third PBODY.
